(19) United States
(12) Patent Application Publication
(10) Pub. No.: US 2003/0045113 A1
(43) Pub. Date: Mar. 6, 2003

(54) Fabrication method of semiconductor integrated circuit device

(75) Inventors: Hiroyuki Enomoto, Mitaka (JP); Hiroshi Kawakami, Hachiouji (JP); Tadashi Umezawa, Ome (JP); Kazutami Tago, Hitachinaka (JP)

Correspondence Address: MILES & STOCKBRIDGE PC, 1751 PINNACLE DRIVE, SUITE 500, MCLEAN, VA, 22102-3833, US

(73) Assignee: Hitachi, Ltd.

(21) Appl. No.: 10/198,125

(22) Filed: Jul. 19, 2002

(30) Foreign Application Priority Data
Sep. 6, 2001 (JP) 2001-270814

(51) Int. Cl. H01L 21/3205; H01L 21/302

(52) U.S. Cl. 438/706; 438/585

(57) ABSTRACT

A fabrication method of a semiconductor integrated circuit device using a gas mixture comprising SF₆, oxygen and nitrogen as a plasma source gas upon dry etching of a W film, a WNx film and a polycrystal silicon film as a gate electrode material by using a silicon nitride film as a mask, the fabrication method capable of ensuring the shape of the gate electrode upon etching fabrication of a gate electrode of a polymetal structure and improving the etching selectivity to the etching stopper film comprising silicon nitride.

### BACKGROUND OF THE INVENTION

This invention concerns a technique for fabricating a semiconductor integrated circuit device and, more in particular, it relates to a technique effective to application for a process of dry etching a conductor layer containing metals as a main ingredient thereby forming a gate electrode.

In CMOSLSI which constitutes circuits with fine MISFET (Metal Insulator Semiconductor Field Effect Transistor) having a gate length of 0.16 μm or less, and DRAM (Dynamic Random Access Memory) which uses a gate electrodes as wirings (word lines), it has been demanded to form the gate electrode by using a low resistance conductive material containing metals as a main ingredient in order to insure high speed operation.

A so-called polymetal in which a high melting metal film is stacked on a polycrystal silicon film has been considered important as a conductive material for use in the gate electrode of this type. Since the polymetal has a sheet resistance as low as about 2 Ω/□, it can be utilized not only as the gate electrode material but also as the wiring material. For the high melting metal, W (tungsten) showing a good low resistance even at a low temperature process of 800° C. or lower and having high electro migration resistance is used for example. Further, in a case where a high melting metal film is stacked directly on the polycrystal silicon film, since there is a worry that adhesion between both of them is lowered or a silicide layer of high resistance is formed at the boundary between both of them upon high temperature heat treatment, an actual polymetal gate electrode comprises three layered conductor films in which a barrier metal film such as made of WNx (tungsten nitride) is interposed between the polycrystal silicon film and the high melting metal film.

The polymetal gate electrode or the metal gate electrode is generally described, for example, in U.S. Pat. Nos. 4,505,028, 5,719,410 and 5,387,540, or IEEE Transaction Electron Devices, Vol. 43, No. 11, November 1996, Akasaka, et al, 1864-1869, Elsevier, Applied Surface Science 117/118 (1997) 312-316, Nakajima, et al, Advanced Metallization Conference, Japan Session, Tokyo Univ. (1995)

Japanese Patent Laid-Open Hei 9(1997)-82686 discloses a technique of anisotropically etching a high metal film selectively to a polycrystal silicon film, upon fabrication of a polymetal gate by using a gas mixture comprising a halogen gas containing at least one of fluorine (F) and chlorine (Cl), and oxygen (O₂) as a plasma source gas. The halogen-containing gas described above can include, for example, SF₆, CF₄ Cl₂, CCl₄ or a mixture of such gases.

Further, it is pointed out in this patent literature that the ratio of the oxygen gas in the gas mixture has to be set within a range of 50 to 80% by volume in order to etch the high melting metal film at a high selectivity to the polycrystal silicon film. Further, it is also pointed out that the etching selectivity does not change even when a third gas such as nitrogen or Ar is added to the gas mixture.

Japanese Patent Laid-Open No. 2000-40696 discloses a technique of preventing the phenomenon that the surface of a polycrystal silicon film is roughened by an SF₆ gas used for the etching of a W film upon forming a gate electrode by dry etching of a polymetal film in which a barrier metal and a W film are stacked on a polycrystal silicon film.

In this patent literature, a mask comprising an organic material or silicon nitride is used and the polymetal film is patterned by plasma etching using the following reaction gases. At first, after etching the W film by using a first reaction gas comprising SF₅+HBr+Cl₂+N₂, overetching is applied successively, to scrape the surface of the barrier metal film and completely remove the W film. Then, after etching the remaining portion of the barrier metal film by using a second reaction gas comprising Cl₂+Ar, overetching is applied successively to scrape the surface of the polycrystal silicon film to completely remove the barrier metal film. In the dry etching, using the second reaction gas, since the barrier metal film is removed by the sputtering effect of Ar ions and, further, the surface of the polycrystal silicon film is scraped by the sputtering effect of the Ar ions and etching effect of the Cl ions, the surface of the polycrystal silicon film is smoothed. Then, the remaining portion of the polycrystal silicon film is etched by using a third reaction gas comprising HBr+Cl₂+O₂ and, finally, the mask is removed by an ashing treatment to obtain a polymetal gate electrode.

### SUMMARY OF THE INVENTION

In recent years, in the fabrication steps for fine MISFET, a so-called SAC (Self Aligned Contact) technique has been adopted as a method of forming contact holes for connecting diffusion layers of a substrate (source, drain) and wirings between narrow gate electrodes, in which the contact holes are formed in self alignment to the gate electrode by selective dry etching utilizing the difference of the etching speeds between the silicon oxide film and the silicon nitride film.

In the polymetal gate fabrication process accompanying the SAC process, a polymetal film (conductive film is formed for example, by stacking polycrystal silicon film, barrier metal and high melting metal film orderly from the lower layer) is at first deposited on a semiconductor substrate to which a gate insulative film is formed and, successively, a silicon nitride film as an etching stopper in the SAC process is deposited thereover. Then, after transferring a gate electrode pattern to a photoresist film coated on the silicon nitride film, exposure and development are conducted to form a resist mask.

Then, the silicon nitride film is patterned by dry etching using the resist mask and, successively, the resist mask is removed and then the polymetal film is patterned by dry etching using the silicon nitride film as a mask.

In the step of dry etching the polymetal film by using the silicon nitride film as the mask, it is required to insure the etching selectivity of the polymetal film to the silicon nitride film sufficiently and conduct etching perpendicularly, that is, anisotropically to the side wall of the polymetal.

However, according to the study made by the present inventors, in a case where the high melting metal film or the barrier metal film is dry etched by using the etching gas as used in the prior art described above, since the selectivity of etching to the silicon nitride film can not be ensured sufficiently, the scraping amount of the silicon nitride film increases and the silicon nitride film can no more function as the etching stopper in the subsequent SAC process.

Further, upon over-etching the high melting metal film or barrier metal film, since the polycrystal silicon film as the underlayer is side etched, it is difficult to anisotropically etch the polymetal film.

This invention intends to provide a technique capable of sufficiently ensuring the etching selectivity of a polymetal film to a silicon nitride film in a case of dry etching the polymetal film using the silicon nitride film as a mask.

This invention further intends to provide a technique capable of anisotropically etching a polymetal film by using a silicon nitride film as a mask.

The foregoing and other objects, as well as novel features of this invention will become apparent with reference to the descriptions of the present specification in conjunction with the appended drawings.

Among the inventions disclosed in the present patent application, outlines for typical examples are to be explained briefly as below.

(1) A fabrication method of a semiconductor integrated circuit device according to this invention includes the following steps of:

(a) forming a first conductive film containing a metal as a main ingredient on the main surface of a semiconductor substrate;

(b) forming a first insulative film containing silicon nitride as a main ingredient on the first conductive film and then patterning the insulative film into a predetermined shape; and

(c) patterning the first conductive film by dry etching using a gas mixture comprising SF₆, oxygen and nitrogen as a plasmas source gas by using the patterned first insulative film as a mask.

(2) A fabrication method of a semiconductor integrated circuit device according to this invention includes the following steps of:

(a) forming a silicon film on the main surface of a semiconductor substrate and then forming a metal film on the silicon film;

(b) forming a first insulative film containing silicon nitride as a main ingredient on the metal film and then patterning the first insulative film to a predetermined shape;

(c) patterning the metal film by dry etching using the patterned first insulative film as a mask and using a first plasma source gas comprising SF₆, oxygen and nitrogen; and

(d) patterning the silicon film by dry etching after the step (c) by using a first plasma source gas or a second plasma source gas different in the composition therefrom, thereby forming plural gate electrodes each comprising the silicon film and the metal film on the main surface of the semiconductor substrate.

### BRIEF DESCRIPTION OF THE DRAWINGS

FIG. 1 is a plan view for a main portion of a semiconductor substrate showing a fabrication method of a semiconductor integrated circuit device as an embodiment according to this invention;

FIG. 2 is a cross sectional view for a main portion of a semiconductor substrate showing a fabrication method of semiconductor integrated circuit device as an embodiment according to this invention;

FIG. 3 is a cross sectional view for a main portion of a semiconductor substrate showing a fabrication method of semiconductor integrated circuit device as an embodiment according to this invention;

FIG. 4 is a cross sectional view for a main portion of a semiconductor substrate showing a fabrication method of semiconductor integrated circuit device as an embodiment according to this invention;

FIG. 5 is a cross sectional view for a main portion of a semiconductor substrate showing a fabrication method of semiconductor integrated circuit device as an embodiment according to this invention;

FIG. 6 is a cross sectional view for a main portion of a semiconductor substrate showing a fabrication method of semiconductor integrated circuit device as an embodiment according to this invention;

FIG. 7 is a cross sectional view for a main portion of a semiconductor substrate showing a fabrication method of semiconductor integrated circuit device as an embodiment according to this invention:

FIG. 8 is a cross sectional view for a main portion of a semiconductor substrate showing a fabrication method of semiconductor integrated circuit device as an embodiment according to this invention;

FIG. 9 is a schematic view for a dry etching apparatus used in an embodiment according to this invention;

FIG. 10 is a cross sectional view for a main portion of a semiconductor substrate showing a fabrication method of semiconductor integrated circuit device as an embodiment according to this invention;

FIG. 11 is a cross sectional view for a main portion of a semiconductor substrate showing a fabrication method of semiconductor integrated circuit device as an embodiment according to this invention;

FIG. 12 is a cross sectional view for a main portion of a semiconductor substrate showing a fabrication method of semiconductor integrated circuit device as an embodiment according to this invention;

FIG. 13 is a cross sectional view for a main portion of a semiconductor substrate showing a fabrication method of semiconductor integrated circuit device as an embodiment according to this invention;

FIG. 14 is a cross sectional view for a main portion of a semiconductor substrate showing a fabrication method of semiconductor integrated circuit device as an embodiment according to this invention;

FIG. 15 is a cross sectional view for a main portion of a semiconductor substrate showing a fabrication method of semiconductor integrated circuit device as an embodiment according to this invention;

FIG. 16 is a plan view for a main portion of a semiconductor substrate showing a fabrication method of semiconductor integrated circuit device as another embodiment according to this invention;

FIG. 17 is a cross sectional view for a main portion of a semiconductor substrate showing a fabrication method of semiconductor integrated circuit device as another embodiment according to this invention;

FIG. 18 is a cross sectional view for a main portion of a semiconductor substrate showing a fabrication method of semiconductor integrated circuit device as another embodiment according to this invention;

FIG. 19 is a cross sectional view for a main portion of a semiconductor substrate showing a fabrication method of semiconductor integrated circuit device as another embodiment according to this invention;

FIG. 20 is a cross sectional view for a main portion of a semiconductor substrate showing a fabrication method of semiconductor integrated circuit device as another embodiment according to this invention;

FIG. 21 is a plan view for a main portion of a semiconductor substrate showing a fabrication method of semiconductor integrated circuit device as another embodiment according to this invention;

FIG. 22 is a cross sectional view for a main portion of a semiconductor substrate showing a fabrication method of semiconductor integrated circuit device as another embodiment according to this invention;

FIG. 23 is a cross sectional view for a main portion of a semiconductor substrate showing a fabrication method of semiconductor integrated circuit device as another embodiment according to this invention;

FIG. 24 is a cross sectional view for a main portion of a semiconductor substrate showing a fabrication method of semiconductor integrated circuit device as another embodiment according to this invention;

FIG. 25 is a cross sectional view for a main portion of a semiconductor substrate showing a fabrication method of semiconductor integrated circuit device as another embodiment according to this invention;

FIG. 26 is a cross sectional view for a main portion of a semiconductor substrate showing a fabrication method of semiconductor integrated circuit device as another embodiment according to this invention; and

FIG. 27 is a cross sectional view for a main portion of a semiconductor substrate showing a fabrication method of semiconductor integrated circuit device as another embodiment according to this invention.

### DETAILED DESCRIPTION OF THE PREFERRED EMBODIMENTS

Preferred embodiments according to this invention are to be explained in details with reference to the drawings. Throughout the drawings for explaining the preferred embodiments, identical member carry same reference numerals for which duplicate explanations will be omitted.

In the preferred embodiments to be described later, they are explained being divided into plural sections or embodiments, when necessary in view of the convenience, they are concerned with each other in such a relation that one is modified examples, details or supplementary explanations for a part or a whole portion of other, unless otherwise specified.

Further, when number of elements (including number, numerical value, quantity and range) is referred to, it is not restricted to any specified number but may be more than or less than the specified number unless otherwise specified or except for case specifically designated or apparently restricted to the specified number in view of principle. Further, in the embodiments to be described below, constituent factors thereof (including elemental steps or the like) are not always essential except for a case where they are considered apparently essential in view of principle.

Further, constituent factors (gas, element, molecule, material, etc.) do not exclude other factors except for cases where they are specified so or are not apparently so in view of principle. Accordingly, in a gas atmosphere for processing wafers, for example, when a particular combination of specified gases are referred to as etchants or etching gases without mentioning for other gases, this does not mean to exclude addition of other etching gases, rare gases such as argon or helium and others, as well as the presence of controlling gases.

In the same manner, in the following embodiments, when the shape and positional relationship of constituent factors are mentioned, they also include those substantially approximate or similar with the shape and the like thereof except for a case where it is distinctly specified and apparently considered not so in view of principle. This is applicable also for the numerical values and ranges described above.

Further, “semiconductor integrated circuit device” referred to in the present specification means not only those prepared on single crystal silicon substrates but also includes those prepared on other substrates such as SOI (Silicon On Insulator) substrates or substrates for use in production of TFT (Thin Film Transistor), unless otherwise specified. Further, “wafer” means, for example, single crystal silicon substrates (generally of a substantial disk shape), SOS substrates, glass substrates and other insulative, semi-insulative or semiconductor substrates, or a composite substrates thereof used for the fabrication of semiconductor integrated circuit devices.

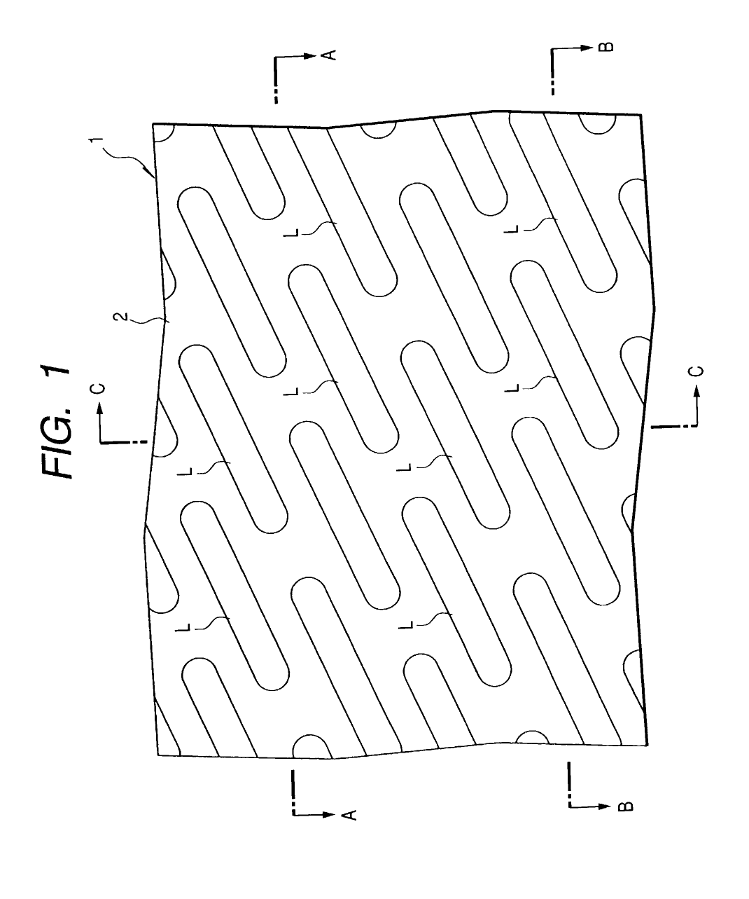

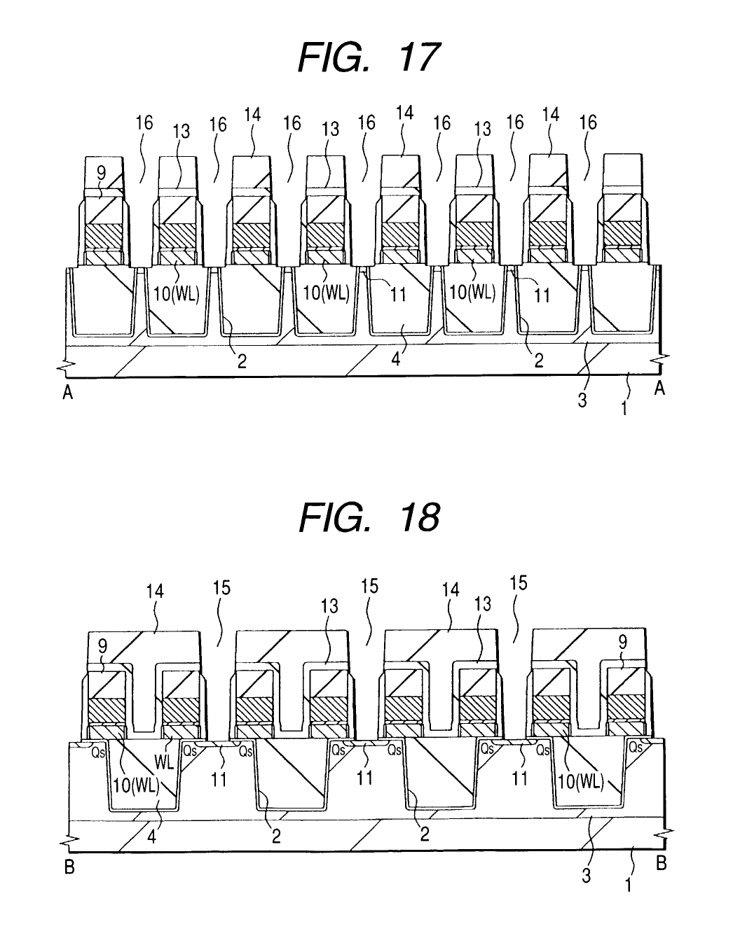

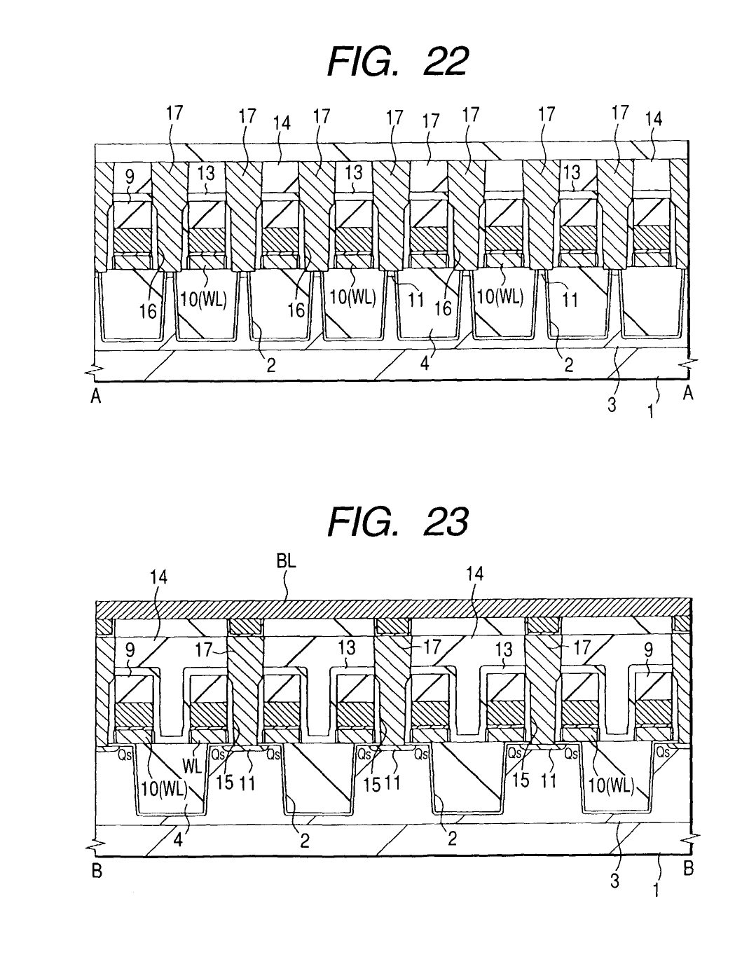

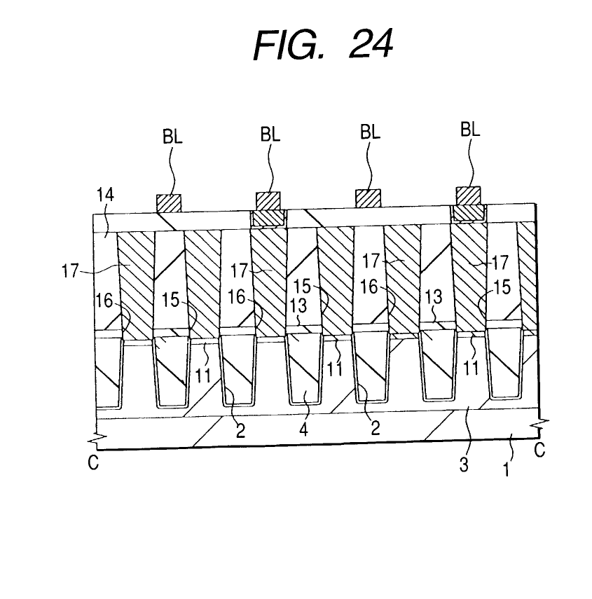

A fabrication method for DRAM as an embodiment of this invention is to be explained in the order of steps with reference to FIG. 1 to FIG. 27.

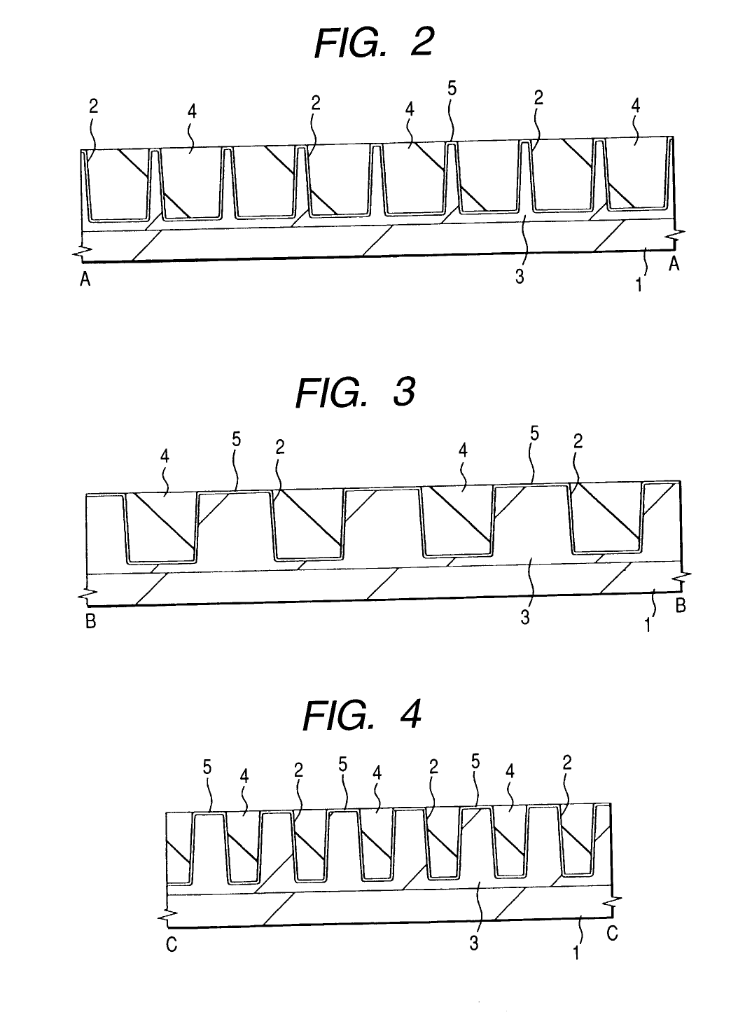

At first, as shown in FIG. 1 (plan view for a main portion of memory array), FIG. 2 (cross sectional view taken along line A-A in FIG. 1), FIG. 3 (cross sectional view taken along line B-B in FIG. 1) and FIG. 4 (cross sectional view taken along line C-C in FIG. 1), device isolation trenches 2 are formed in device isolation regions on the main surface of a semiconductor substrate 1 comprising, for example, p-type single crystal silicon (hereinafter referred to as a substrate or, sometimes, as a wafer) . The device isolation trench 2 is formed by etching the surface of the substrate 1 to form a trench of about 300 to 400 nm depth, successively, depositing a silicon oxide film 4 (about 600 nm thickness) on the substrate 1 including the inside of the trench by a CVD (Chemical Vapor Deposition) method and then polishing to flatten the silicon oxide film 4 by a chemical mechanical polishing (CMP) method. The silicon oxide film 4 is deposited, for example, by a plasma CVD method using oxygen (or ozone) and tetraethoxy silane (TEOS) as a source gas and then densifying the film by dry oxidation at about 1000° C.

As shown in FIG. 1, elongate island-like active regions (L) each surrounded with the device isolation trench 2 are simultaneously formed in plurality by forming the device isolation trenches 2. As will be described later, memory cell selecting MISFETQs having one of source and drain in common are formed each by two in each of the active regions (L).

Then, after forming a p-type well 3 by ion implanting boron (B) to the substrate 1 and successively cleaning the surface of the p-type well 3 with a fluoric acid (HF) type cleaning liquid, a clean gate insulative film 5 (about 6 nm thickness) comprising silicon oxide is formed on the surface of the active region (L) of the p-type well 3 by thermally oxidizing the substrate 1. The gate insulative film 5 may be a silicon oxide film formed by thermal oxidation of the substrate 1, as well as may be a silicon nitride type insulative film having a higher dielectric constant, or metal oxide type insulative film (tantalum oxide film, titanium oxide film or the like). The highly dielectric insulation films are formed by depositing a film on the substrate 1 by a CVD method or a sputtering method.

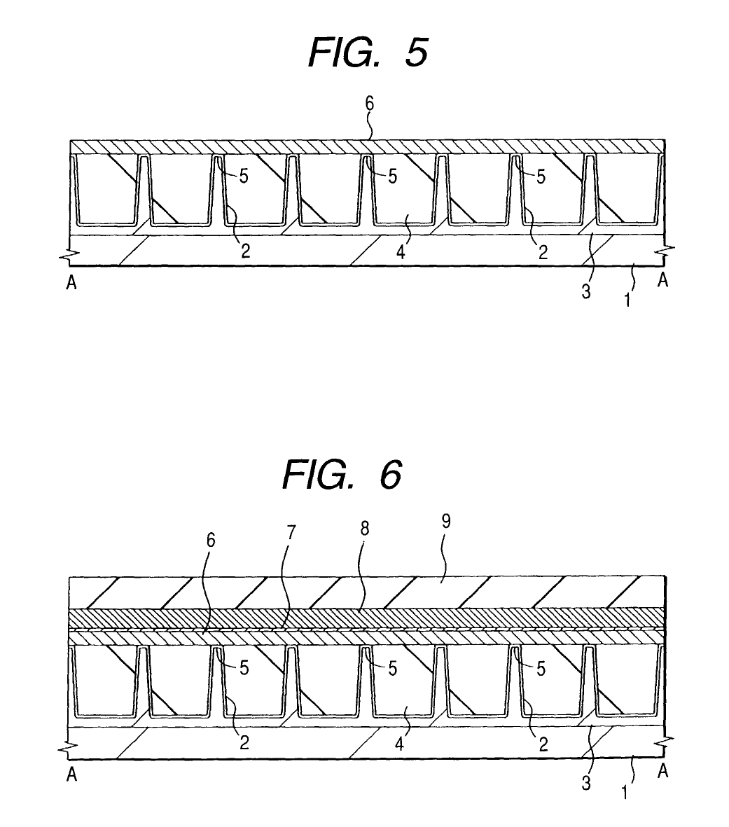

Then, as shown in FIG. 5, an n-type polycrystal silicon film 6 doped with phosphorus (B) is deposited on the gate insulative film 5. The polycrystal silicon film 6 is deposited, for example, by a CVD method using monosilane (SiH₄) and phosphine (PH₃) as a source gas (film deposition temperature=about 630° C.) and the film thickness was controlled to about 70 nm, For lowering the electric resistance, the phosphorus concentration in the polycrystal silicon film 6 is adjusted to 1.0×10¹⁹ cm³ or more. Instead of the polycrystal silicon film 6, a silicon film containing germanium (Ge) by from 5% to about 50% at the maximum may also be used. When germanium is incorporated in silicon, there is an advantage that the ohmic resistance with the metal film in the upper layer is reduced due to narrowing of the silicon band gap or increase in the solid solution limit of impurities. Germanium is incorporated in silicon by a method of introducing germanium by ion implantation to a silicon film and, in addition, a method of depositing a silicon film containing germanium by a CVD method using monosilane (SiH₄) and GeH₄.

Then, after cleaning the surface of the polycrystal silicon film 6 with hydrofluoric acid, a tungsten nitride (WNx) film 7 of about 5 nm thickness and a W film 8 of about 80 nm thickness were deposited continuously over the polycrystal silicon film 6 by a sputtering method as shown in FIG. 6 and, successively, a silicon nitride film 9 of about 220 nm thickness is deposited over the W film 8 successively. The WNx film 7 is a barrier layer for preventing reaction between the polycrystal silicon film 6 and the W film 8. The silicon nitride film 9 on the W film 8 may be a stacked film of a silicon oxide film and a silicon nitride film.

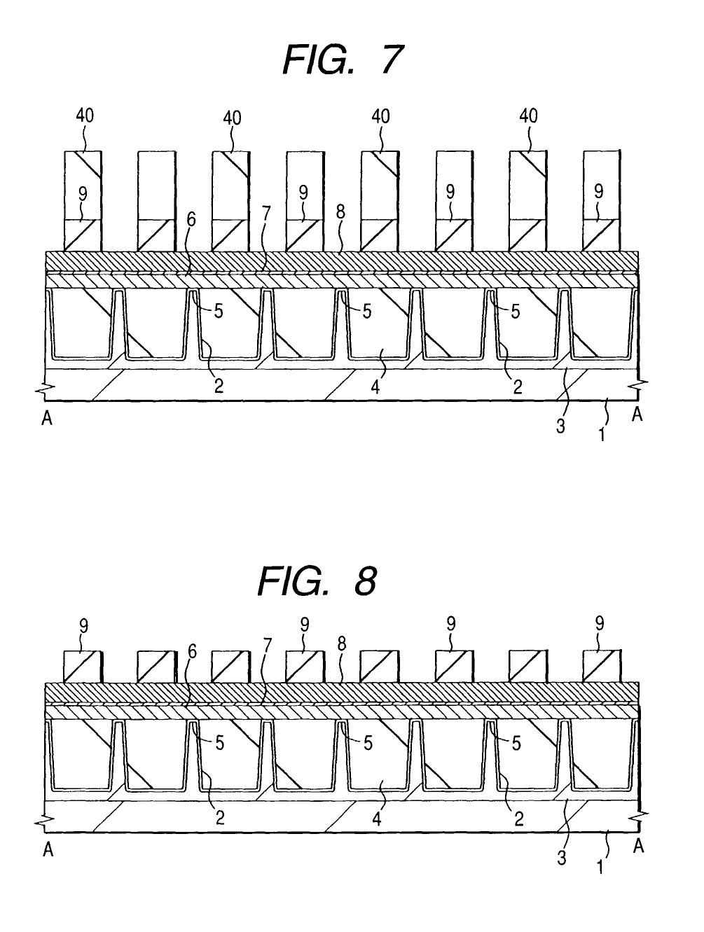

Then, as shown in FIG. 7, the silicon nitride film is dry etched using a photoresist 40 formed on the silicon nitride film 8 as a mask. In this stage, the width of the silicon nitride film along the right-to-left direction (gate length direction) is 0.16 μm and the distance with the adjacent silicon nitride film 9 is 0.16 μm. For the etching of the silicon nitride film 9, a gas mixture formed by adding oxygen and Ar to a hydrofluoro carbon type gas, for example, CHF₃ or CH₂F₂ is used and, in addition, well known gases used in the etching of silicon nitride films can also be used.

Then, as shown in FIG. 8, the photoresist film 40 is removed by ashing. Then, a gate electrode is formed by dry etching the gate electrode material (W film 8, WNx film 7 and polycrystal silicon film 6) of the underlayer by using the silicon nitride film 9 as a mask.

Then, conditions required for the dry etching is (a) to ensure the etching selectivity of the gate electrode material to the silicon nitride film 9 sufficiently and (b) etch the side wall of the gate electrode material in perpendicularly, that is, anisotropically.

The silicon nitride film 9 is used as an etching stopper for preventing scraping of the gate electrode in the SAC step, that is, when the silicon oxide film deposited over the gate electrode is dry etched to form contact holes that reach the substrate 1. If an etching selectivity to the silicon nitride film 9 can not be insured upon dry etching of the gate electrode material, the thickness of the silicon nitride film 9 is reduced and the film can not function as an etching stopper in the SAC step.

The gas mixture comprising, for example, CF₄+Cl₂+oxygen+nitrogen is known as a gas for etching W film or WNx film. When the present inventors applied the gas mixture to the dry etching of the gate electrode material, the selectivity to the silicon nitride film (9) as a etching mask is only about 1, so that the thickness of the silicon film was reduced greatly. The selectivity of the gas mixture to the silicon nitride film is low because carbon (C) contained in CF₄ scrapes the silicon nitride film. That is, a compound obtained by the reaction of an intermediate product formed by dissociation of CF₄ and silicon nitride (CNF or the like) easily evaporates to promote etching of the silicon nitride film. With the same reason as described above, when etching is conducted by using the gas mixture and, successively, the surface of the polycrystal silicon film (6) as the underlayer is over-etched, even when the surface of the polycrystal silicon film (6) is protected by oxidation with an oxygen gas, the intermediate product formed by dissociation of CF₄ and silicon react with oxygen to form a compound which evaporates easily and less deposits on the side wall, so that the oxidative protective effect is reduced.

Further, when a gas containing CF₄ and Cl₂ like that the gas mixture described above is decomposed by plasmas, a compound of carbon (C) and fluorine (F) is deposited on the chamber wall and, further, fluorine (F) and chlorine (Cl) are substituted to form a compound (CCl₄). Since the compound formed by etching by W film or WNx film tend to be absorbed to the compound (CCl₄), when a lot of wafers are processed continuously, the compound (CCl₄) is deposited on the inner wall of the processing chamber in the etching chamber, on which compounds formed by etching of W film or WNx film are adsorbed, so that a great amount of deposits are deposited on the inner wall of the processing chamber. Since the deposits are evaporated again in the processing chamber to hinder the reproducibility of etching, it results in failure of fabrication shape of the gate electrode.

As described above, in a case of etching the W film or WNx film by using the silicon nitride film as the mask, use of a hydrofluorocarbon type gas such as CF₄ or CHF₃ is not preferred in view of the etching selectivity. Further, use of a gas containing a hydrofluoric carbon type gas and Cl₂ is not preferred in view of the control for the fabrication shape (attainment of anisotropic etching).

In view of the above, for anisotropically etching a polymetal type gate electrode material (W film, WNx film and polycrystal silicon film) by using the silicon nitride film as the mask, it is required to select a gas mixture containing both gas species for depositing deposits on the side wall of the gate electrode material and gas species for etching the deposits. Further, it is required that the product from the mask is less evaporative. If it is easily evaporative, the mask material (silicon nitride film) tends to be etched to lower the etching selectivity of the gate electrode material to the silicon nitride film. Further, in a case where the deposits are not deposited on the side wall of the gate electrode material, since the gate electrode material exposed on the side wall is exposed to the gas and side-etched, the fabrication shape for the side wall is not vertical. On the other hand, even when the deposits are deposited on the side wall, if a gas for etching the deposits is not present, since the thickness of the deposits increases along with progress of etching, the fabrication shape of the side wall is tapered and anisotropic etching can not be attained also in this case.

In view of the above, the present inventors have calculated characteristics caused by decomposition of various kinds of gas species (adsorbability and depositability) according to molecular orbit calculation based on the density functional theory and, as a result, reached a conclusion that a gas mixture comprising SF₆, oxygen and nitrogen is optimal as an etching gas for the polymetal type gate electrode material.

SF₆ gas in the gas mixture is a gas that etches the metal type material (W film, WNx film) . That is, F ions or F radicals formed by dissociation of SF₆ react with the metal type material to proceed etching. On the other hand, nitrogen in the gas mixture is a gas that protects the side wall of the metal type material (W film, WNx film) . That is, when N ions or N radicals formed by dissociation of nitrogen react with the metal type material and further reacts with the reaction product of the metal type material and SF₆, easily depositing compounds are deposited on the side wall. Further, since the gas mixture does not contain the hydrofluorocarbon type such as CF₄ or CHF₃, the reaction product for promoting etching of the silicon nitride film is less caused. Accordingly, compared with a case of using the hydrofluorocarbon gas, etching selectivity to the silicon nitride film is improved by twice or more. That is, by the use of the gas mixture comprising SF₆ and nitrogen, anisotropic etching for the metal type material can be attained, as well as the selectivity of the metal type material to the silicon nitride film can be improved.

Further, since the gas mixture does not deposit a great amount of deposits on the inner wall of the processing chamber as in the case of a gas mixture of a hydrofluoro carbon type gas and Cl₂, reproducibility of etching can be kept favorably to improve the shape controllability of the gate electrode.

The gas mixture described above further contains oxygen. This oxygen is a gas for suppressing etching of the polycrystal silicon film. That is, when the W film and the WNx film are sequentially etched and the surface of the polycrystal silicon film as the underlayer is over-etched successively, oxides formed by the reaction of the silicon and oxygen suppresses scraping of the polycrystal silicon film to improve the etching selectivity of the WNx film to the polycrystal silicon film.

As described above, since oxygen in the gas mixture is used mainly with an aim of suppressing etching of the polycrystal silicon film upon over-etching of the WNx film, it is not always necessary upon etching of the W film and the WNx film. Accordingly, in the stage of etching the W film and the WNx film, a gas mixture only consisting of SF₆ and nitrogen may be used and oxygen may be added in a stage of over-etching the surface of the polycrystal silicon film as the underlayer. However, since oxygen also has an effect of suppressing the scraping of the silicon nitride film as an etching mask, it is preferred to add oxygen from the initial stage with a view point of improving the etching selectivity to the silicon nitride film.

NF₃ is a gas species having a function similar with SF₆ contained in the gas mixture. Accordingly, a gas mixture containing NF₃ instead of SF₆ or together with SF₆ may also be used. However, since NF₃ is toxic, a care should be taken upon handling. Further, since NO has a function of suppressing side etching of the polycrystal silicon film like oxygen, a gas mixture containing NO instead of oxygen or together with oxygen may also be used. However, NO also is toxic, a care should be taken upon handling. Further, since oxygen and Cl₂ have a function of suppressing the side etching of the polycrystal silicon film, Cl₂ may be added further to the gas mixture.

In addition, with an aim, for example, of improving plasma conditions, addition of a rare gas (Ar, He, etc.) to the gas mixture may also be permitted but the etching speed is lowered. Further, since the use of various kinds of gases complicates gas supply systems of an etching apparatus, it is preferred that the number of the kind of gas species contained in the gas mixture is smaller considering the cost of the etching apparatus. Accordingly, a combination of a gas mixture comprising SF₆, oxygen and nitrogen is optimal.

The gas mixture comprising SF₆, oxygen and nitrogen is a suitable gas for use in the etching step of the metal type material (W film, WNx film) and the over-etching step for the surface of the polycrystal silicon film and, in over-etching, Cl₂ may also be added for suppressing side etching. Taking the etching speed and the selectivity to the silicon nitride film into consideration, it is preferred to use Cl₂ for the etching of the polycrystal silicon film. Further, since addition of oxygen suppresses etching of the polycrystal silicon film, it is desirable to use a gas mixture of oxygen and Cl₂ upon over-etching of the polycrystal silicon film to suppress the scraping of the gate insulative film 5 as the underlayer.

Then, explanation is to be made to a concrete example of the dry etching process by using the gas mixture comprising SF₆, oxygen and nitrogen. The etching apparatus and the etching conditions (gas flow rate ratio, RF power) employed herein are shown merely as examples then and they are not restricted to such an example.

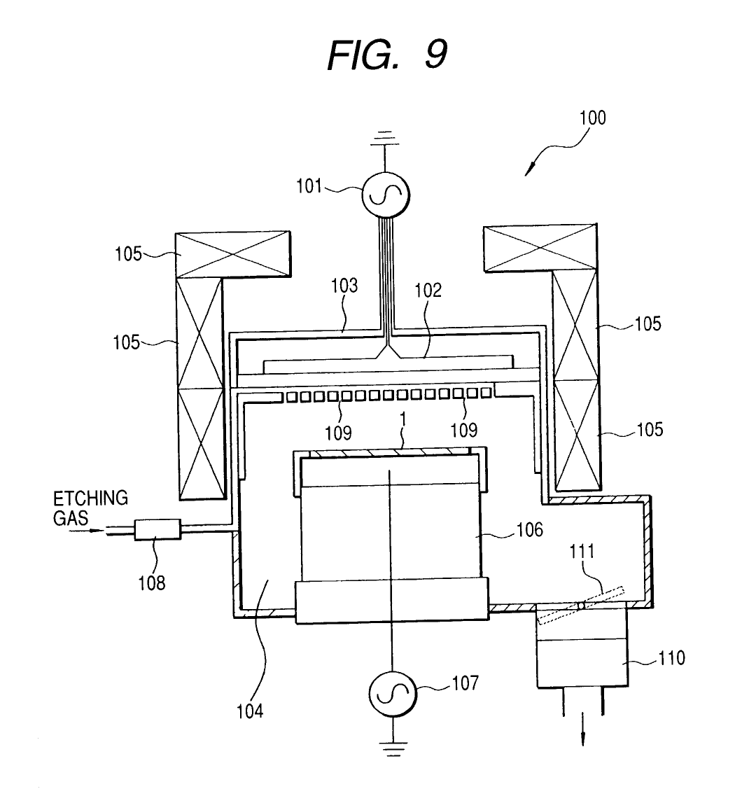

FIG. 9 is a schematic view showing a dry etching apparatus 100 used for the etching of a gate electrode material (W film 8, WNx film 7 and polycrystal silicon film 6).

A radio frequency waves at 300 MHz to 900 MHz formed from a radio frequency power source 101 are introduced passing through an antenna (counter electrode) 102 into a processing chamber 104. The radio frequency waves cause resonance between the antenna 102 and an antenna ground 103 at the vicinity thereof and propagate efficiently into the processing chamber 104. The radio frequency waves inter act with ECR (Electron Cyclotron Resonance) generated from solenoid coils 105 disposed at the periphery of the processing chamber 104 or more axial magnetic fields to form plasmas at a high density (1×10¹⁷/m³ or more) in a low pressure region of about 0.3 Pa.

A wafer (substrate) 1 is stacked and secured to the upper surface of a stage 106 disposed at the center of the processing chamber 104 by an electrostatic chuck mechanism not illustrated. The distance between the wafer 1 secured on the upper surface of the stage 106 and the antenna 102 is optionally set within a range from 20 mm to 150 mm. Radio frequency waves at 400 KHz to 13.5 MHz formed from a second radio frequency power source 107 are applied to the stage 106 and ion incident energy to the wafer 1 is controlled independently of the generation of the plasmas. An etching gas is introduced, after optimization of the flow rate by a gas flow controller 108, through a gas inlet 109 into the processing chamber 104 and decomposed by the plasmas. Further, exhaust gases are exhausted by an exhaustion pump 110 out of the processing chamber 104. The pressure in the inside of the processing chamber 104 is controlled by on/off of a control valve 111 disposed in the exhaustion system. The temperature of each of the portions in contact with the plasmas such as inner wall of the processing chamber 104, the stage 106 and the gas inlet 109 is controlled by a temperature controller not illustrated.

For the etching apparatus used for the etching of the gate electrode material, various kinds of dry etching apparatus capable of decomposing gas species described above by plasmas can be used such as a microwave plasma etching apparatus utilizing microwaves at 2.45 GHz generated, for example, from a magnetron, a TCP (Transfer Coupled Plasma) type dry etching apparatus utilizing radio frequency induction, or a helicon wave plasma etching apparatus utilizing helicon waves in addition to the dry etching apparatus shown in FIG. 9. In addition, the gas pressure, flow rate ratio and the stage temperature are not restrict to the conditions described above and they can be optionally optimized in accordance with the apparatus used or the like.

For etching the gate electrode material (W film 8, WNx film 7 and polycrystal silicon film 6) by using the dry etching apparatus 100 described above, at first, a wafer (substrate) 1 in the state shown in FIG. 8 is mounted on the stage 106 in the processing chamber 104, and the surface temperature of the stage 106 is set to 50° C. or less, preferably, 30° C. or less. In this embodiment, the surface temperature of the stage 106 is fixed at 20° C. during etching.

Then, SF₆ and the nitrogen are introduced into the processing chamber 104 through the gas inlet 109. The flow rate for each of the gases are set at SF₆=25 ml/min and nitrogen=15 ml/min, and the pressure in the processing chamber 104 is set to 0.3 Pa. Then, the power of the first radio frequency power source 101 is set to 700 W and the power of the second radio frequency wave power source 107 is set to 50 W respectively and plasmas are fired.

Successively, the W film 8 and the WNx film 7 are continuously etched anisotropically as shown in FIG. 10 by setting the flow rate of the gases introduced into the processing chamber 104 at SF₆=15 ml/min, oxygen=5 ml/min and nitrogen=15 ml/min and setting the pressure in the processing chamber 104 to 0.3 Pa, the power of the radio frequency power source 101 to 500 W and the power the radio frequency power source 107 to 30 W, respectively.

Then, W film 8 and the WNx film 7 are over-etched by 30% and, after completely removing the films, the gas species introduced into the processing chamber 104 are switched from the gas mixture to Cl₂. The flow rate of Cl₂ is set to 50 ml/min and the pressure in the processing chamber 104 is set to 0.2 Pa. Then, the polycrystal silicon film 6 is etched anisotropically while setting the power of the first radio frequency power source 101 to 500 W, the power of the second radio frequency power source 107 to 30 W respectively. Successively, 30% over-etching applied to completely remove the polycrystal silicon film 6 while setting the flow rate of the gas introduced into the processing chamber as: Cl₂=45 ml/min, oxygen=5 ml/min and the pressure in the processing chamber 104 to 0.4 Pa, the power of the radio frequency power source 101 to 500 W, the power of the radio frequency power source 107 to 5 W, respectively.

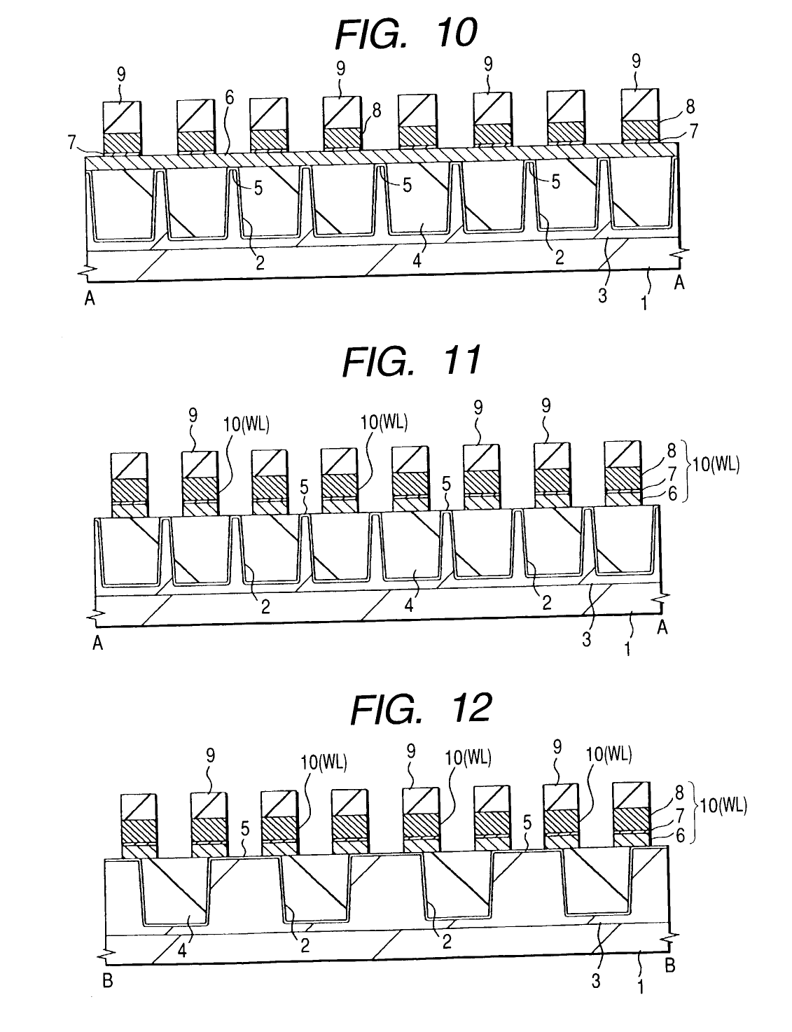

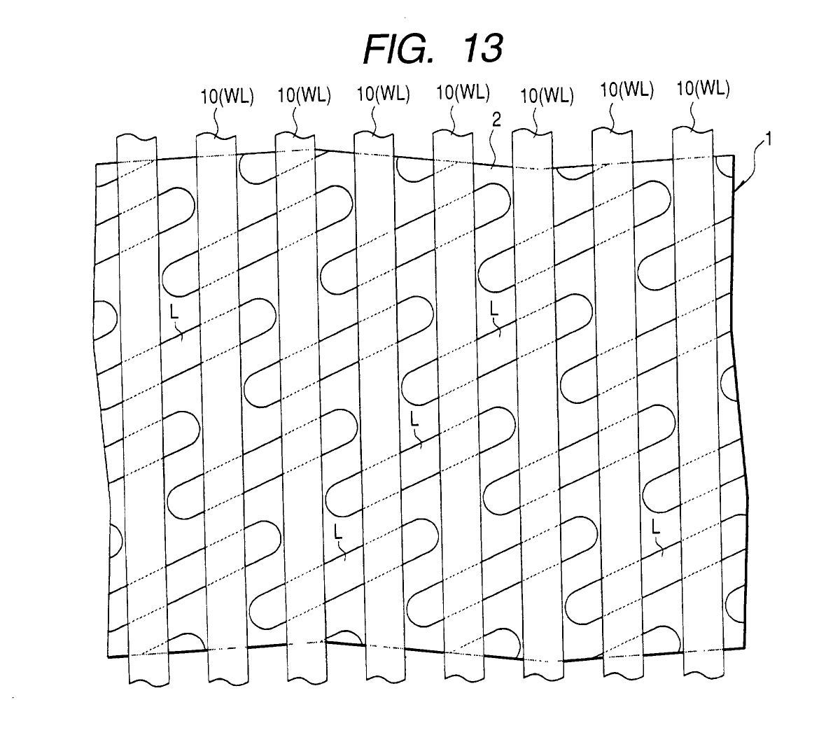

As shown in FIG. 11 and FIG. 12, a gate electrode 10 of a polymetal structure comprising the W film 8, the WNx film 7 and the polycrystal silicon film 6 is completed by the steps so far. The gate electrode 10 constitutes word line WL in a region other the active region (L). FIG. 13 is a plan view of the gate electrode 10 (word line WL).

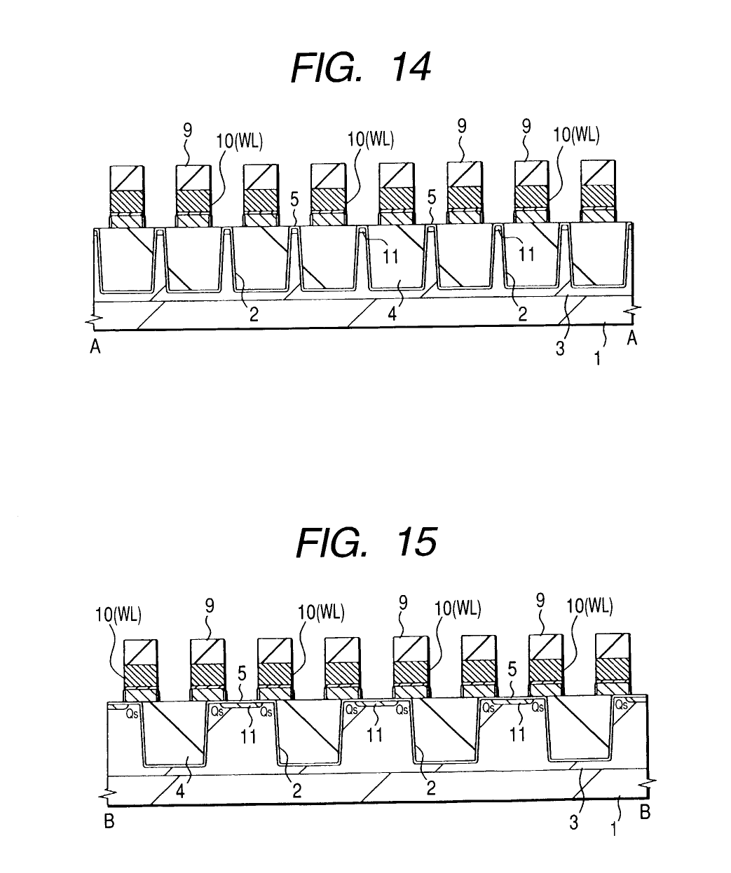

Then, as shown in FIG. 14 and FIG. 15, As (arsenic) or P (phosphorus) are ion implanted to the p-type well 3 to form n-type semiconductor regions 11 (source, drain) on both sides of the gate electrode 10. A memory cell electrode MISFETQs is substantially completed by the steps so far.

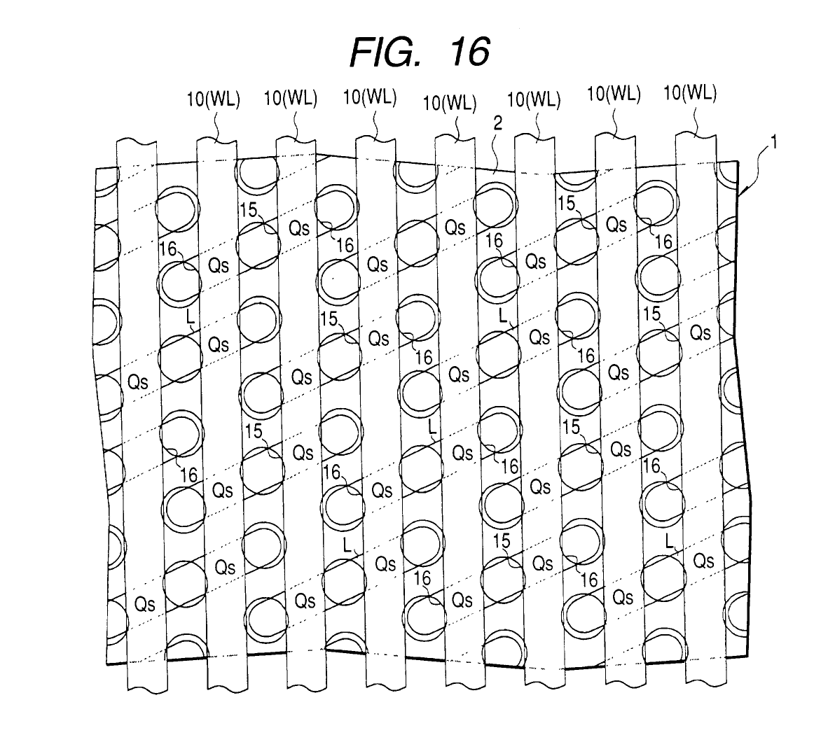

Then, as shown in FIG. 16 to FIG. 18, a silicon nitride film 13 (50 nm thickness) and a silicon oxide film 14 (about 600 nm thickness) are deposited on the substrate 1 by a CVD method and, after flattening the surface of the silicon oxide film 14 by a chemical mechanical successively, by a polishing method, the silicon oxide film 14 and the silicon nitride film 13 are dry etching by using a photoresist film (not illustrated) as a mask, to form contact holes 15 and 16 above the source - drain (n-type semiconductor region 11) of the memory cell selecting MISFETQs. Etching to the silicon oxide film 14 is applied under the condition where the selectivity to the silicon nitride 13 is high while etching to the silicon nitride film 13 is applied under the condition where the etching selectivity to silicon or silicon oxide is high. Thus, the contact holes 15, 16 are formed in self alignment to the gate electrode 10 (word line WL). In this embodiment, since scraping of the silicon nitride film 9 as the etching stopper over the gate electrode 10 (word line WL) can be suppressed in the dry etching step of the gate electrode 10 (word line WL) described above, a failure of exposing the gate electrode 10 (word line WL) to the side wall of the contact holes 15 and 16 in dry etching for forming the contact holes 15 and 16 can be prevented reliably.

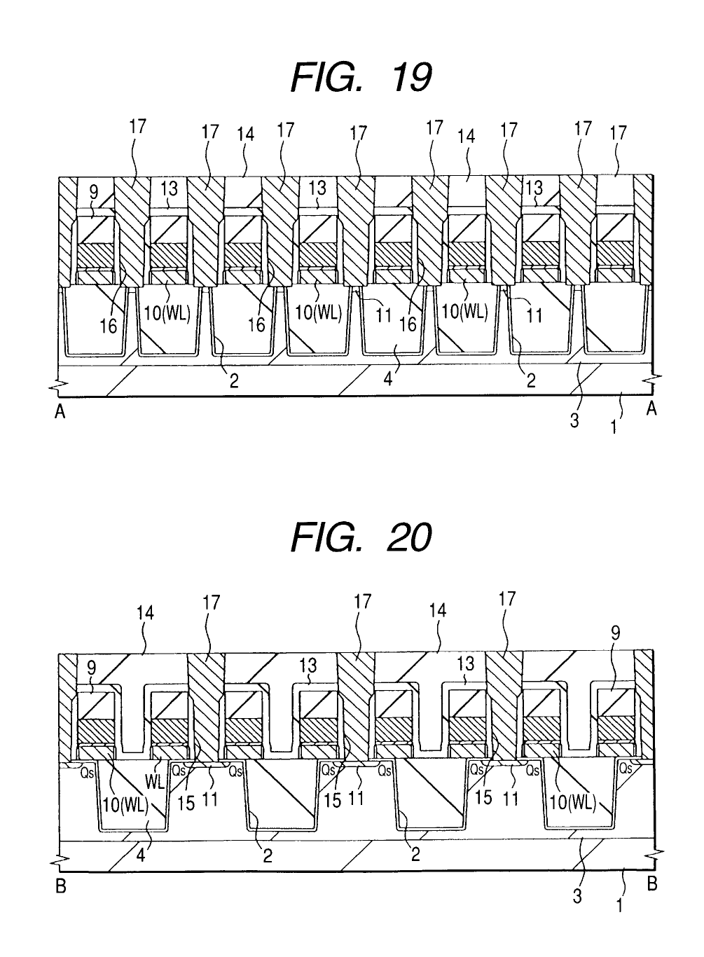

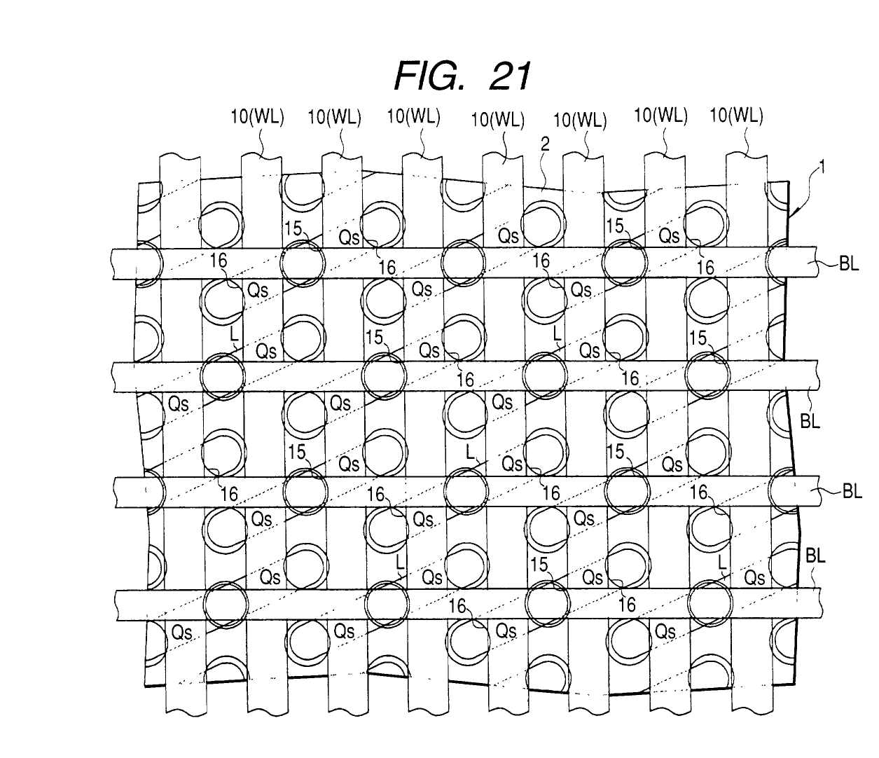

Then, as shown in FIG. 19 and FIG. 20, after burying plugs 17 comprising polycrystal silicon in the inside of the contact holes 15 and 16, bit lines BL to be connected electrically with the plugs 17 in the contact holes 15 are formed as shown in FIG. 21 to FIG. 24. The bit line BL is formed, for example, by patterning the W film deposited over the silicon oxide film 8 by the sputtering method.

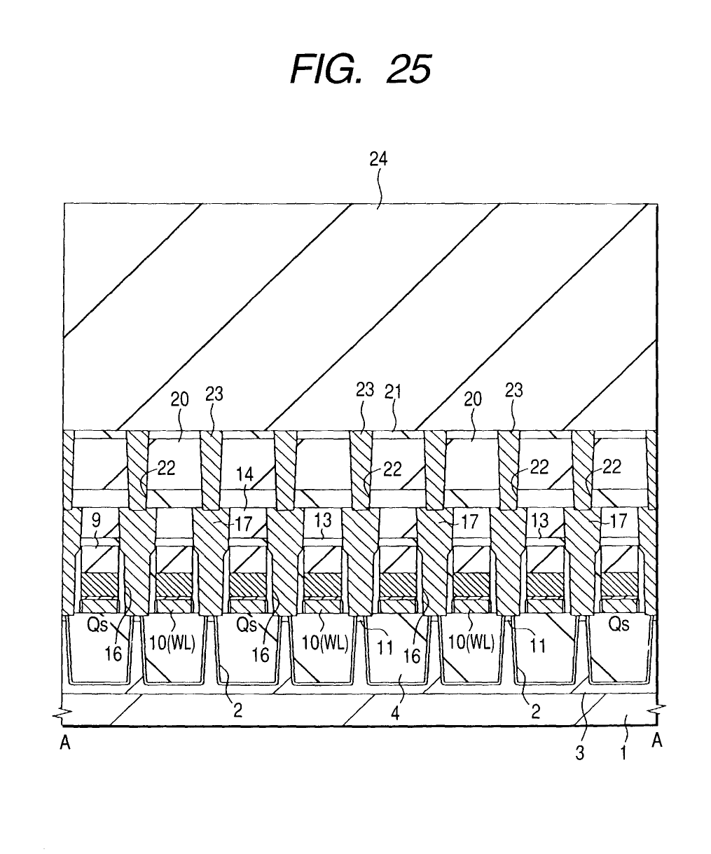

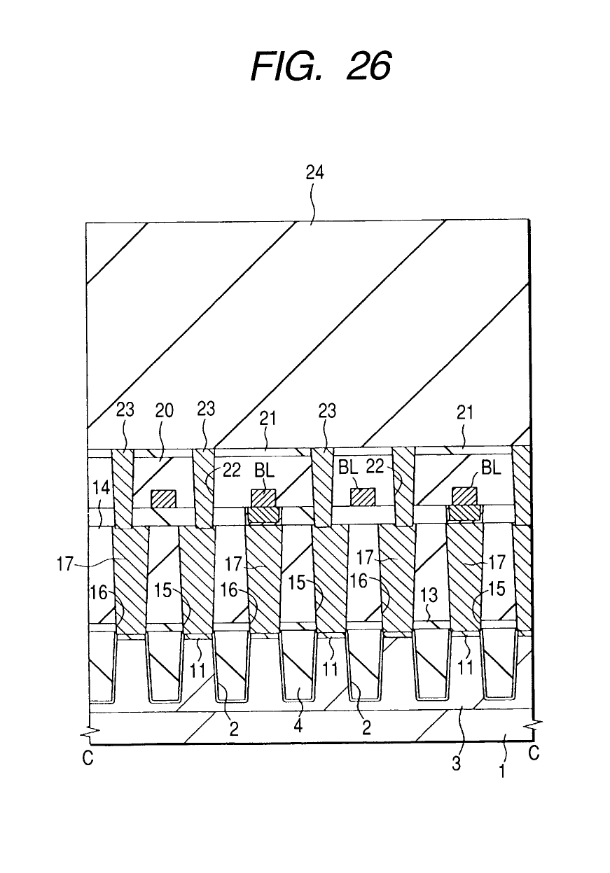

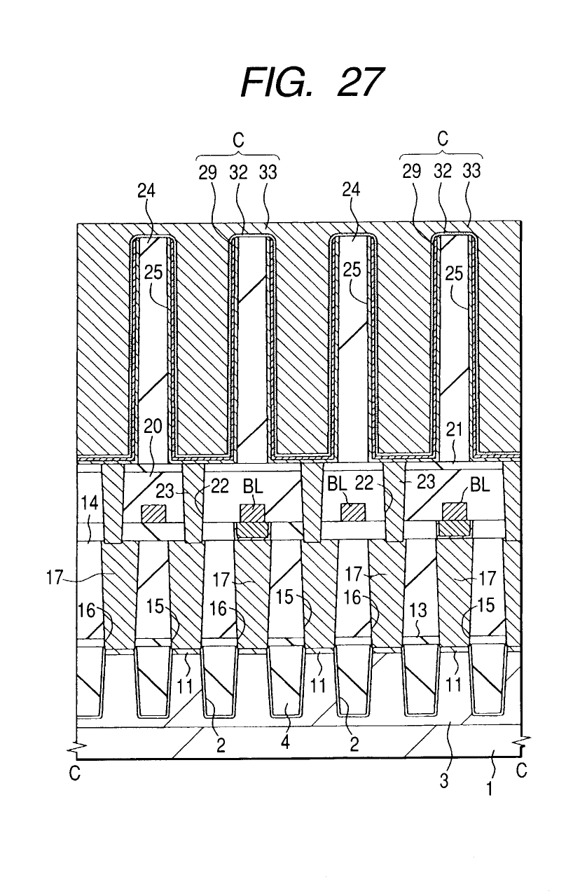

Then, as shown in FIG. 25 and FIG. 26, through holes 22 are formed in the silicon oxide film 20 and the silicon nitride film 21 deposited over the bit line BL and, successively, after burying plugs 23 comprising polycrystal silicon in the inside of the through holes 22, a silicon oxide film 24 is deposited on the silicon film 21.

Then, as shown in FIG. 27, after forming trenches 25 by dry etching the silicon oxide film 24, information storage capacitance devices C each constituted with a lower electrode 29, a tantalum oxide film (capacitance insulation film) 32 and an upper electrode 33 are formed in the inside of the trenches 25. By the steps so far, a memory cell constituted with memory cell selecting MISFETQs and information storage capacitance device C connected in series therewith are substantial completed.

The invention made by the present inventors has been explained specifically with reference to the embodiments of the invention but the invention is no restricted only to the embodiments describe above and may be varied variously within a range not departing the gist thereof.

The effects obtained by typical examples among those disclosed in the present application are simply explained as below.

When the polymetal film is dry etched using the silicon nitride film as the mask, the etching selectivity of the polymetal film to the silicon nitride film can be insured by using a gas mixture comprising SF₆, oxygen and nitrogen as a plasma source gas.

When the polymetal film is dry etched by using the silicon nitride film as the mask, the polymetal film can be dry etched anisotropically by using the gas mixture comprising SE₆, oxygen and nitrogen as the plasma source gas.

When the polymetal film is dry etched by using the silicon nitride film as the mask, source gas the amount of deposits deposited on the inner wall of the chamber in the etching apparatus can be reduced to attain dry etching with less aging change by the use of the gas mixture comprising SF₆, oxygen and nitrogen as the plasma.

What is claimed is:

1. A fabrication method of a semiconductor integrated circuit device comprising the steps of:
(a) forming a first conductive film containing a metal as a main ingredient on the main surface of a semiconductor substrate;
(b) forming a first insulative film containing silicon nitride as a main ingredient on the first conductive film and then patterning the insulative film into a predetermined shape; and
(c) patterning the first conductive film by dry etching using a gas mixture comprising SF₆, oxygen and nitrogen as a plasmas source gas by using the patterned first insulative film as a mask.

2. A fabrication method of a semiconductor integrated circuit device according to claim 1, wherein the first conductive film comprises a silicon film, a barrier film formed on the silicon film and a high melting metal film formed on the barrier film.

3. A fabrication method of a semiconductor integrated circuit device according to claim 2, wherein the barrier film contains tungsten nitride as a main ingredient and the high melting metal film contains tungsten as a main ingredient.

4. A fabrication method of a semiconductor integrated circuit device according to claim 1, wherein a gate electrode of MISFET is formed by patterning the first conductive film.

5. A fabrication method of a semiconductor integrated circuit device according to claim 1, wherein the dry etching in the step (c) is conducted while setting the temperature of a stage supporting the semiconductor substrate to 50° C. or lower.

6. A fabrication method of a semiconductor integrated circuit device according to claim 5, wherein the dry etching in the step (c) is conducted while setting the temperature of the stage supporting the semiconductor substrate to 30° C. or lower.

7. A fabrication method of a semiconductor integrated circuit device according to claim 1, wherein the gas mixture contains NF₃ instead of SF₆ or together with SF₆.

8. A fabrication method of a semiconductor integrated circuit device comprising the steps of:
(a) forming a silicon film on the main surface of a semiconductor substrate and then forming a metal film on the silicon film;
(b) forming a first insulative film containing silicon nitride as a main ingredient on the metal film and then patterning the first insulative film to a predetermined shape;
(c) patterning the metal film by dry etching using the patterned first insulative film as a mask and using a first plasma source gas comprising SF₆, oxygen and nitrogen; and
(d) patterning, after the step (c), the silicon film by dry etching by using a first plasma source gas or a second plasma source gas different in the composition therefrom, thereby forming plural gate electrodes each comprising the silicon film and the metal film on the main surface of the semiconductor substrate.

9. A fabrication method of a semiconductor integrated circuit device according to claim 8, wherein a barrier film is further provided between the silicon film and metal film, and the metal film and the barrier film are continuously patterned in the step (c).

10. A fabrication method of a semiconductor integrated circuit device according to claim 9, wherein the barrier film contains tungsten nitride as a main ingredient and the metal film contains tungsten as a main ingredient.

11. A fabrication method of a semiconductor integrated circuit device according to claim 8, wherein the dry etching in the step (c) and the dry etching in the step (d) are applied continuously in one identical processing chamber.

12. A fabrication method of a semiconductor integrated circuit device according to claim 8, wherein the dry etching in the step (c) and the dry etching in the step (d) are applied while setting the temperature of the stage for supporting the semiconductor substrate to 50° C. or lower.

13. A fabrication method of a semiconductor integrated circuit device according to claim 12, wherein the dry etching in the step (c) and the dry etching in the step (d) are applied while setting the temperature of the stage for supporting the semiconductor substrate to 30° C. or lower.

14. A fabrication method of a semiconductor integrated circuit device according to claim 8, wherein the second plasma source gas used in the dry etching in the step (d) is a gas mixture of chlorine and oxygen.

15. A fabrication method of a semiconductor integrated circuit device according to claim 8, wherein the first plasma source gas used in the dry etching in the step (c) further contains chlorine.

16. A fabrication method of a semiconductor integrated circuit device according to claim 8, wherein the first plasma source gas used in the dry etching in the step (c) contains NF₃ instead of SF₆ or together with SF₆.

17. A fabrication method of a semiconductor integrated circuit device according to claim 8, wherein the first plasma source gas used in the dry etching in the step (c) contains NO instead of oxygen or together with oxygen.

18. A fabrication method of a semiconductor integrated circuit device according to claim 8, wherein an insulative film containing silicon oxide as a main ingredient is further interposed between the metal film and the first insulative film.

19. A fabrication method of a semiconductor integrated circuit device according to claim 8, wherein the step (c) further includes a first step of patterning a portion of the metal film by dry etching using a third plasma source gas comprising SF₆ and oxygen, and a second step of patterning, after the first step, the remaining portion of the metal film by dry etching using a first plasma source gas comprising SF₆, oxygen and nitrogen.

20. A fabrication method of a semiconductor integrated circuit device according to claim 8, further including, after the step (d), the steps of:
(e) forming, on the semiconductor substrate formed with plural gate electrodes, a second insulative film containing silicon nitride as a main ingredient and having such a film thickness as not burying the space regions of plural gate electrodes;
(f) forming, on the second insulative film, a third insulative film containing silicon oxide as a main ingredient and having a thickness as burying the space regions of plural gate electrodes;
(g) forming open holes in the third insulative film above the space regions by dry etching using the first insulative film and the second insulative film as an etching stopper; and
(i) dry etching the second insulative film exposed to the bottom of the open holes to expose the surface of the semiconductor substrate, thereby forming contact holes in the second and the third insulative films in the space regions.
